(19) United States
(12) Patent Application Publication
(10) Pub. No.: US 2006/0204811 A1
(43) Pub. Date: Sep. 14, 2006

(54) Adaptor type fuel cell and assembly structure thereof

(75) Inventors: Chien-Lang Wang, Taipei (TW); Usi-Ming Shu, Taipei (TW)

Correspondence Address: G. LINK Co., LTD, 3550 Bell Road, MINOOKA, IL, 60447, US

(73) Assignee: ANTIG TECHNOLOGY Co,Ltd.

(21) Appl. No.: 11/076,123

(22) Filed: Mar. 10, 2005

(51) Int. Cl. H01M 8/24; H01M 8/10; H05K 7/06

(52) U.S. Cl. 429/32; 429/34; 361/760

(57) ABSTRACT

The present invention is related to an adaptor type fuel cell which partly comprises the fuel cell manufactured by the print circuit board (PCB) that utilizes the process of PCB, wherein the fuel cell comprises one or more membrane electrode assemblies (MEAs) which is sandwiched between the PCB and characterized in that one first connector is placed on the PCB and electrically connected to the MEAs. Furthermore, the stand plugging into the assembly structure or the adaptor type fuel cell of the plugging device plugging into the motherboard therefore forms a power supply source.

### FIELD OF THE INVENTION

The present invention relates to a fuel cell, especially to an adaptor type fuel cell.

### BACKGROUD OF THE INVENTION

The used fuel cell uses hydrogen included in fuel like methanol which forms the current loop after oxidation-reduction reaction to supply electrical power. This kind of fuel cell requiring the reactant with liquid fuel like methanol and the main product after reaction being the water and carbon dioxides needs the container structure to fill liquid fuel and the structure to drive fuel flow. However, it limits the structure for used fuel cell to make used fuel cell design supply specific current and specific voltage. In case of connecting used fuel cells in a series or parallel, these connected fuel cells will occupy a huge volume and have a loose structure to make used fuel cells in principle fail to form modularized connections.

Therefore, the present invention is based on the disadvantages of used fuel cells and desires for improvement to invent an adaptor type fuel cell to make the fuel cell so convenient as to use the interfacial adaptor card.

### SUMMARY OF THE INVENTION

The first object of the present invention is to provide a fuel cell and use it as the interfacial adaptor card.

The second object of the present invention is to provide an assembly structure to assemble an adaptor type fuel cell and also to be a power supply.

The third object of the present invention is to provide a motherboard used for electronic instrument, the motherboard is capable of directly plugging into the adaptor type fuel cell for use and utilizing electrical power supplied by the adaptor type fuel cell.

To achieve the above objects, the present invention provides an adaptor type fuel cell which partly comprises the fuel cell manufactured by the print circuit board (PCB) that utilizes the process of PCB, wherein the fuel cell comprises one or more membrane electrode assemblies (MEAs) which is sandwiched between the PCB and characterized in that a first connector is placed on the PCB and electrically connected to the MEAs, furthermore, the stand plugging into the assembly structure or the adaptor type fuel cell of the plugging device plugging into the motherboard therefore forms a power supply source.

### BRIEF DESCRIPTION OF THE DRAWINGS

The above objects and advantages of the present invention will become more apparent with reference to the appended drawings wherein:

FIG. 1 shows the structure figure of the present invention adaptor type fuel cell;

FIG. 2 shows the structure figure of the assembly structure of the present invention's adaptor type fuel cell; and

FIG. 3 shows the structure figure of motherboard of the present invention's assembly structure.

### DETAILED DESCRIPTION OF THE INVENTION

The present invention provides an adaptor type fuel cell 10 which is designed as the type of interfacial adaptor card to plug into the motherboard of the electronic instrument, for instance, the fuel cell 10 is plugged into the motherboard of the computer or to use the stand 20 of the present invention plugging into a series of fuel cells 10 in order to make the fuel cell more popularly and conveniently applied to versatile electronic instruments.

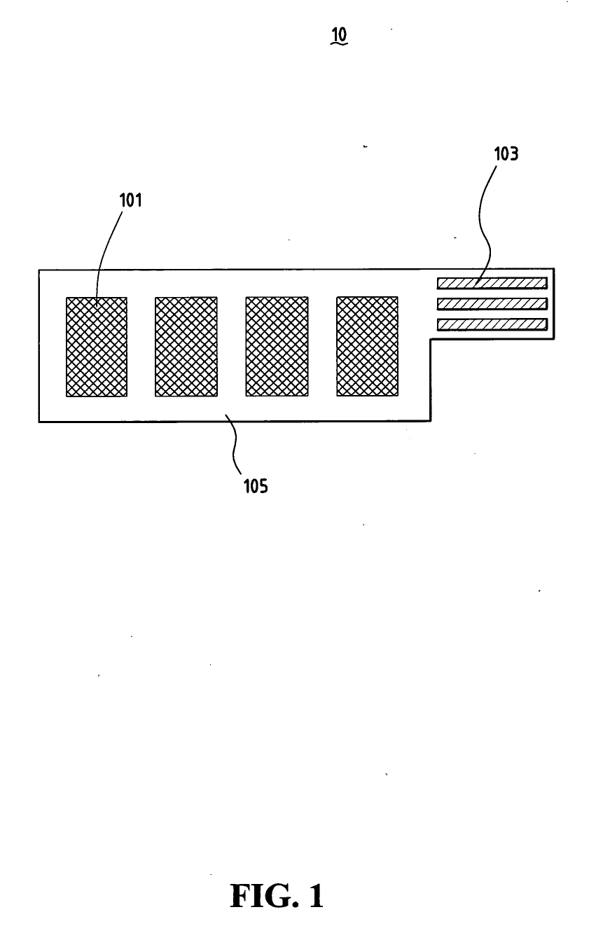

FIG. 1 shows the structure figure of the present invention's adaptor type fuel cell. The present invention adaptor type fuel cell 10 mainly utilizes the process of PCB for manufacture, consequently, the other elements to constitute fuel cell 10 except membrane electrode assemblies (MEAs) 101 are capable of using the materials of PCB. Fuel cell 10 mainly comprises one or more MEAs 101, the first connector 103 and PCB 105, wherein MEAs 101 are sandwiched between PCB 105 and MEAs 101 are capable of directly utilizing the MEAs used for methanol fuel cell. The first connector 103 is placed on PCB 105 and connects to the positive and negative electrodes of MEAs 101, that is, one terminal of the first connector 103 is used as the positive electrodes of all MEAs 101 and the other terminal is used as the negative electrodes of all MEAs 101. The implemented means of the first connector 103 is capable of forming the golden fingers on PCB 105 or the male connector soldering on PCB 105, even or the female connector soldering on PCB 105. The first connector 103 in FIG. 1 is to use the golden fingers as the embodiment.

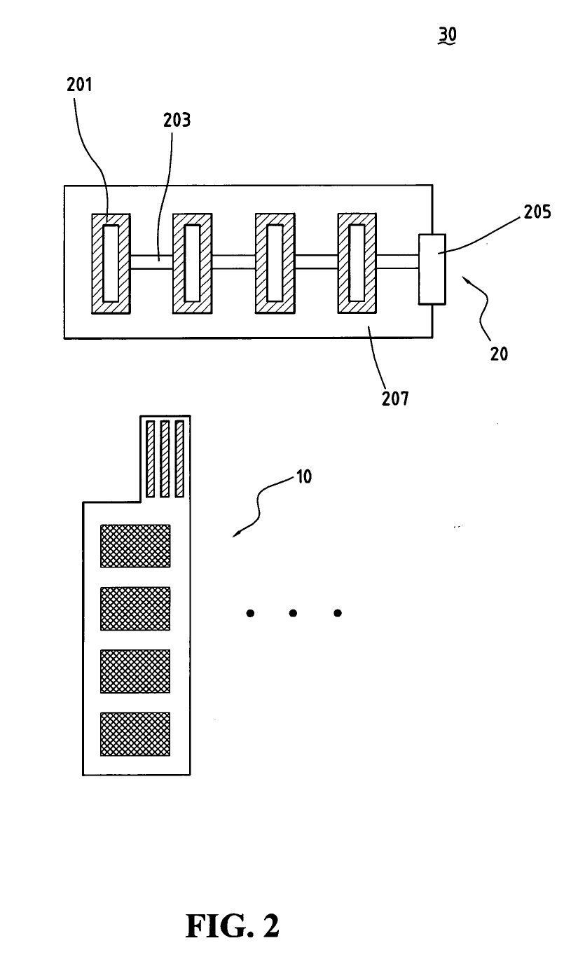

FIG. 2 shows the structure figure of assembly structure of the present invention's adaptor type fuel cell. The assembly structure 30 mainly comprises the adaptor type fuel cell 10 and the stand 20 used to fix and electrically connect to adaptor fuel cell 10. The assembly structure 30 is capable of being used as a power supply and connecting outward to the input ends of electronic instruments by the third connector 205 of the stand 20 to supply electrical power for electronic instruments. The stand 20 mainly comprises at least one second connector 201, electrical circuit 203, the third connector 205 and the substrate 207. Each second connector 201 is used to electrically connect to one adaptor type fuel cell 10. To choose what type of second connector 201 depends on the first connector 103 of the adaptor type fuel cell 10, the second connector 201 used by the present invention is to match the first connector 103 to choose the plug-in connector. The plug-in connector is easy to plug in the adaptor type fuel cell 10 or plug out adaptor type fuel cell 10. Furthermore, this plug-in connector, except with the electrical connection, possesses a fastening mechanism to fix the adaptor type fuel cell 10. Electrical circuit 203 is electrically connecting to each second connector 201, the embodiment of the present invention is a serial and/or parallel voltage circuitry used to have a preset voltage for all adaptor fuel cells 10 plugged on the stand 20, for instance, 12 volts of preset voltage. Again, except for serial and/or parallel voltage circuitry, electrical circuit 203 includes power management circuits used to efficiently manage the electrical power produced by adaptor type fuel cell 10.

The third connector 205 is connected to the output end of electrical circuit 203, for instance, the output end of the serial and/or parallel voltage circuitry outputs 12 volts of preset voltage from the third connector 205. The substrate 207 is to use the PCB to make the above second connector 201, electrical circuit 203 and the third connector 205 placed on the substrate 207.

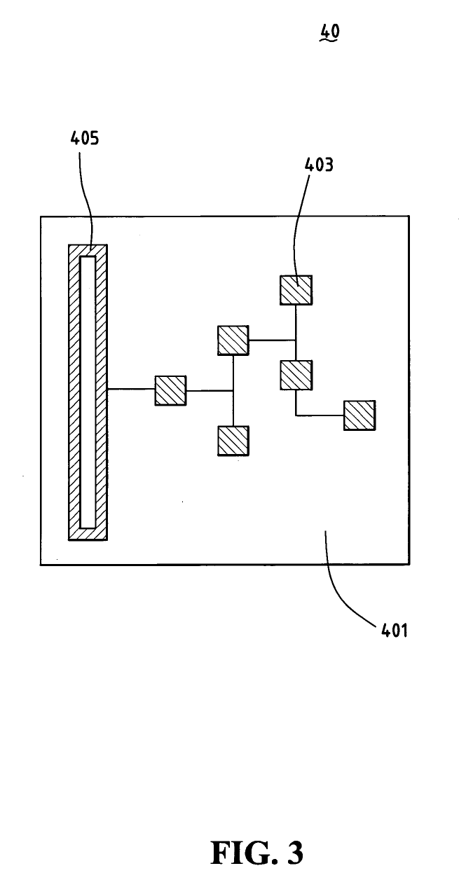

FIG. 3 shows the structure figure of motherboard of the present invention's assembly structure. The embodiment of the present invention provides a motherboard 40 capable of being the computer's motherboard, or the motherboard of the portable electronic instrument, or the motherboard of another electronic instrument. Motherboard 40 mainly comprises a PCB 401, one or more electronic components 403 and at least one plug-in device 405, wherein electronic components 403 are soldered on PCB 401 and the plug-in device 405 is placed on PCB 401, for instance, using the plug-in connector which matches the first connector 103 be the embodiment of plug-in device 405 and is soldered on PCB 401.The quantity of plug-in device 405 is possible to be one or above one to make the first connector 103 of each adaptor type fuel cell 10 individually plug into each plug-in device 405 according to the quantity of plug-in device 405 in order to electrically connect adaptor fuel cell 10 and these electronic components 403 and also supply electrical power for these electronic components 403 by plug-in device 405 from adaptor type fuel cell 10. Furthermore, parts of electronic components 403 soldered on PCB 401 are used for adaptor type fuel cell 10, for instance, forming the above serial and/or parallel voltage circuitry and power management circuit by these parts of electronic components 403.

The present invention provides an adaptor type fuel cell 10, assembly structure 30 and motherboard 40 capable of achieving the following effects:
1. The present invention provides an assembly structure 30 making the fuel cell form a modularized power supply source;
2. By the aid of the present invention of adaptor type fuel cell 10 makes the convenient usage of fuel cell as the interfacial adaptor card and also completely utilizes the plug-in property to make the maintenance of adaptor type fuel cell 10 more easier; and
3. The motherboard 40 of the present invention is capable of directly plugging adaptor type fuel cell for use to make the motherboards of versatile electronic instruments with electrical power themselves and solve the power supply issue of electronic instruments.

Although the present invention has disclosed one embodiment as the above, it does not imply to limit the present invention, any person who is skilled in the art could make any change or modification within the spirit and scope of the present invention, however, it belongs to the scope of the present invention, the protective scope of the present invention is defined by the following claims.

What is claimed is:

1. An adaptor type fuel cell, comprising:
a fuel cell, which partly uses materials of a print circuit board (PCB) for manufacturing that utilizes the manufacturing process of PCB, wherein the fuel cell comprises one or more membrane electrode assemblies (MEAS) which is sandwiched between the PCB and characterized in that a first connector is placed on the PCB and electrically connected to the MEAs.

2. The adaptor type fuel cell as defined in claim 1, wherein said first connector is the golden finger formed on the PCB.

3. The adaptor type fuel cell as defined in claim 1, wherein said first connector is the male connector soldered on the PCB.

4. The adaptor type fuel cell as defined in claim 1, wherein said first connector is the female connector on the PCB.

5. The adaptor type fuel cell as defined in claim 1, wherein said first connector individually electrically connects to the positive and negative electrodes of said MEAs.

6. An assembly structure used for adaptor type fuel cell, comprising:
at least one adaptor type fuel cell as defined in claim 1;
a stand, having:
at least one second connector, which is used to plug-in to electrically connect to the first connector of the adaptor type fuel cell;
an electrical circuit, which is used to electrically connect to the second connector;
a substrate, wherein the second connector is placed on the PCB and the electrical circuit is placed on the substrate.

7. The assembly structure as defined in claim 6, wherein the substrate is a PCB.

8. The assembly structure as defined in claim 6, wherein the electrical circuit is a serial and/or parallel voltage circuitry used to connect in series and/or parallel to the positive and negative electrodes of the adaptor type fuel cells to have a preset voltage.

9. The assembly structure as defined in claim 8, comprising in advance one third connector which electrically connects to the output end of the voltage circuitry to output the preset voltage.

10. A motherboard used to the electronic instrument, comprising:
a print circuit board (PCB);
one or more electronic components soldered on the PCB;
a plug-in device, which is placed on the PCB and plugs the adaptor type fuel cell as defined in claim 1, wherein the adaptor type fuel cell supplies electrical power for the electronic components via the plug-in device.

11. The motherboard as defined in claim 10, wherein the motherboard is the computer motherboard.

12. The motherboard as defined in claim 10, wherein the plug-in device connects to the first connector of the adaptor type fuel cell.

13. The motherboard as defined in claim 10, wherein parts of the electronic components form a serial and/or parallel circuitry used to connect the positive and negative electrodes of the adaptor type fuel cell in serial and/or parallel to have a preset voltage.
